(19) United States
(12) Patent Application Publication
(10) Pub. No.: US 2023/0282573 A1
(43) Pub. Date: Sep. 7, 2023

(54) INTERCONNECT FEATURE WITH NARROW TOP SECTION AND WIDE BOTTOM SECTION

(71) Applicant: Intel Corporation, Santa Clara, CA (US)

(72) Inventors: Leonard P. Guler, Hillsboro, OR (US); Charles H. Wallace, Portland, OR (US); Tahir Ghani, Portland, OR (US)

(73) Assignee: Intel Corporation, Santa Clara, CA (US)

(21) Appl. No.: 17/685,536

(22) Filed: Mar. 3, 2022

(51) Int. Cl. H01L 23/528; H01L 23/535; H01L 21/768

(52) U.S. Cl. CPC H01L 23/5283; H01L 23/535; H01L 21/76805; H01L 21/76895

(57) ABSTRACT

An integrated circuit device includes a device layer comprising a plurality of transistor devices, and an interconnect layer above the device layer. The interconnect layer includes a conductive interconnect feature. In an example, the interconnect feature includes (i) a bottom portion having a first diameter, and (ii) a top portion above the bottom portion. In an example, the top portion has a second diameter that is less than the first diameter by at least 10%. In an example, the interconnect feature includes a monolithic body of conductive material that is within both the top portion and the bottom portion.

### BACKGROUND

Fabrication of microelectronic devices involves forming electronic components on microelectronic substrates, such as silicon wafers. These electronic components may include transistors, resistors, capacitors, and other active and passive devices, with overlying interconnect features (e.g., conductive vias and conductive lines) to route signals and power to and/or from the electronic components.

Scaling of microelectronic devices results in reduced pitch of the scaled interconnect features. Due to unintended technical limitations in the process to form the scaled interconnect features, misalignments in forming the scaled interconnect features may result in unintended electrical shorting between two interconnect features. To this end, there remain non-trivial challenges with respect to forming scaled interconnect features.

### BRIEF DESCRIPTION OF THE DRAWINGS

FIG. 1A illustrates a cross-sectional view of a section of an integrated circuit (IC) comprising an interconnect layer above a device layer comprising a plurality of active devices, wherein the interconnect layer comprises an interconnect feature (e.g., a conductive via) within a dielectric material, wherein the interconnect feature has a relatively narrower top portion and a relatively wider bottom portion, and wherein the interconnect feature comprises a monolithic body of conductive material within both the top portion and the bottom portion, in accordance with an embodiment of the present disclosure.

FIG. 1B illustrate a magnified perspective view of the interconnect feature of FIG. 1A, in accordance with an embodiment of the present disclosure.

FIG. 1C illustrates a plan view of the interconnect layer including the interconnect feature, in accordance with an embodiment of the present disclosure.

FIG. 1D illustrates the interconnect layer of FIGS. 1A-1C between (i) an upper interconnect layer comprising a plurality of upper conductive features arranged at a first pitch Pu and (ii) a lower layer comprising a plurality of lower conductive features arranged at a second pitch P1 that is higher than the first pitch Pu, wherein the interconnect feature of the interconnect layer of FIGS. 1A-1C conductively couple one of the upper conductive features to one of the lower conductive features, in accordance with an embodiment of the present disclosure.

FIG. 2 illustrates a flowchart depicting a method of forming an IC (such as the IC of FIGS. 1A-1C) comprising an interconnect layer above a device layer comprising a plurality of active devices, wherein the interconnect layer comprises an interconnect feature (e.g., a conductive via) that has a relatively narrower top portion and a relatively wider bottom portion, and wherein the interconnect feature comprises a monolithic body of conductive material within both the top portion and the bottom portion, in accordance with an embodiment of the present disclosure.

FIGS. 3A, 3B1, 3B2, 3B3, 3C1, 3C2, 3C3, 3D1, 3D2, 3D3, 3E1, 3E2, 3E3, 3F1, 3F2, 3F3, and 3G illustrate various views of an IC (such as the IC of FIGS. 1A, 1B, and 1C) in various stages of processing, in accordance with an embodiment of the present disclosure.

FIG. 4A illustrates a cross-sectional view of a section of an IC comprising an interconnect layer above a device layer comprising a plurality of active devices, wherein the interconnect layer comprises an interconnect feature (e.g., a conductive via) that has (i) a relatively narrower top portion within a top dielectric material, and (ii) a relatively wider bottom portion within a bottom dielectric material, and wherein the interconnect feature comprises a monolithic body of conductive material within both the top portion and the bottom portion, in accordance with an embodiment of the present disclosure.

FIG. 4B illustrate a magnified perspective view of the interconnect feature of FIG. 4A, in accordance with an embodiment of the present disclosure.

FIG. 4C illustrates a plan view of the interconnect layer including the interconnect feature, in accordance with an embodiment of the present disclosure.

FIG. 5 illustrates a flowchart depicting a method of forming an IC (such as the IC of FIGS. 4A-4C) comprising an interconnect layer above a device layer comprising a plurality of active devices, wherein the interconnect layer comprises an interconnect feature (e.g., a conductive via) that has (i) a relatively narrower top portion within a top dielectric material, and (ii) a relatively wider bottom portion within a bottom dielectric material, and wherein the interconnect feature comprises a monolithic body of conductive material within both the top portion and the bottom portion, in accordance with an embodiment of the present disclosure.

FIGS. 6A, 6B, 6C, 6D, and 6E illustrate cross-sectional views of an IC (such as the IC of FIGS. 4A, 4B, and 4C) in various stages of processing, in accordance with an embodiment of the present disclosure.

FIG. 7 illustrates a computing system implemented with integrated circuit structures having one or more interconnect features formed using the techniques disclosed herein, in accordance with some embodiments of the present disclosure.

These and other features of the present embodiments will be understood better by reading the following detailed description, taken together with the figures herein described. In the drawings, each identical or nearly identical component that is illustrated in various figures may be represented by a like numeral. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles (e.g., curved or tapered sidewalls and round corners), and some features may have surface topography or otherwise be non-smooth, given real-world limitations of fabrication processes. Further still, some of the features in the drawings may include a patterned and/or shaded fill, which is merely provided to assist in visually identifying the different features. In short, the figures are provided merely to show example structures.

### DETAILED DESCRIPTION

Provided herein are integrated circuit structures including a conductive interconnect feature having a relatively narrow top portion and a relatively wide bottom portion. In one embodiment, an integrated circuit device includes a device layer comprising a plurality of transistor devices, and an interconnect layer above the device layer. The interconnect layer includes a conductive interconnect feature. In an example, the interconnect feature includes (i) a bottom portion having a first diameter, and (ii) a top portion above the bottom portion. In an example, the top portion has a second diameter that is less than the first diameter by at least 10%. In an example, the interconnect feature includes a monolithic body of conductive material that is within both the top portion and the bottom portion.

In another embodiment, an integrated circuit device includes a device layer comprising a plurality of active devices, and an interconnect layer above the device layer. In an example, the interconnect layer includes an interconnect feature comprising a monolithic body of conductive material extending from a bottom surface of the interconnect feature to a top surface of the interconnect feature. In an example, a first diameter of the bottom surface of the interconnect feature is greater than a second diameter of a top surface of the interconnect feature by at least 10%.

In yet another one embodiment, a method of forming an integrated circuit comprises forming one or more layers of dielectric material above a device layer that comprises a plurality of transistors; forming a recess extending within the one or more layers; and widening a bottom portion of the recess, without correspondingly widening a top portion of the recess. In an example, as a result of widening the bottom portion of the recess, a first diameter of the bottom portion of the recess is greater than a second diameter of the top portion of the recess by at least 10%. In an example, the method further comprises subsequent to widening the bottom portion of the recess, depositing a monolithic body of conductive material within the recess, to form an interconnect feature within the recess. In an example, the interconnect feature has (i) a bottom portion having the first diameter, and (ii) a top portion above the bottom portion, where the top portion has the second diameter. Numerous variations, embodiments, and applications will be apparent in light of the present disclosure.

### General Overview

As previously noted, there remain non-trivial challenges with respect to forming scaled interconnect features. For example, assume an intermediate interconnect layer between (i) an upper interconnect layer comprising a plurality of upper interconnect features and (ii) a lower interconnect layer comprising a plurality of lower interconnect features. Assume that a pitch “Pu” of the upper interconnect features is less than a pitch “P1” of the lower interconnect features. An intermediate interconnect feature of the intermediate interconnect layer conductively couples (i) a first lower interconnect feature of the lower interconnect layer and (ii) a first upper interconnect feature of the upper interconnect layer. Assume that a second upper interconnect feature and a third upper interconnect feature are adjacent to the first upper interconnect feature. Now, because the pitch Pu of the upper interconnect features is relatively less (e.g., compared to the pitch P1), if the upper interconnect features are misaligned with respect to the intermediate interconnect layer, chances of unintended electrical shorting between the intermediate interconnect feature and the second upper interconnect feature (or between the intermediate interconnect feature and the third upper interconnect feature) increases.

Accordingly, techniques are provided herein to form an IC in which an intermediate interconnect feature is relatively narrow at a top surface of the intermediate interconnect feature, and is relatively wide at a bottom surface of the intermediate interconnect feature. For example, a top portion of the intermediate interconnect feature has a top diameter dt that is relatively less than a bottom diameter db of a bottom portion of the intermediate interconnect feature, in cases where the intermediate interconnect feature is cylindrical in nature (other intermediate interconnect features may have other geometric shapes, such as square, rectangular, trapezoidal, tapered, or other shape).

Continuing with the above discussed example of the intermediate interconnect layer between the upper interconnect layer and the lower interconnect layer, the narrow top surface of the intermediate interconnect feature reduces chances of unintended electrical shorting between the intermediate interconnect feature and the above discussed second and/or third upper interconnect features. For example, even if the upper interconnect layer is formed with slight misalignment with respect to the intermediate interconnect layer, due to the narrow top surface of the intermediate interconnect feature, a greater lateral distance may be maintained between the intermediate interconnect feature and the second and/or third upper interconnect features, thereby reducing changes of unintended electrical shorting.

As discussed, a bottom portion of the intermediate interconnect feature is relatively wider (e.g., compared to the top portion). Accordingly, this reduces a contact resistance between the intermediate interconnect feature and the first lower interconnect feature. Note that due to the relatively greater pitch P1 of the lower interconnect features, chances of electrical shorting are less between the intermediate interconnect feature and another lower interconnect feature. In an example, the intermediate interconnect layer including the intermediate interconnect feature is above a device layer comprising a plurality of active devices, such as transistors.

In an example, the intermediate interconnect feature (also referred to herein simply as an interconnect feature) may be formed using a number of approaches. One example methodology includes using a liner layer, where the interconnect feature extends through a layer of dielectric material that is etch selective to the liner layer. Another example methodology includes using etch selectivity of two layers of dielectric materials, through which the interconnect feature extends.

In one such example embodiment where the intermediate interconnect feature is formed using the liner layer, a recess is initially formed within and through a layer of dielectric material, where the recess has a diameter of dt. The liner layer is then sputtered on sidewalls of the recess. In an example, in the sputtering process, the liner layer is formed on a top portion of the sidewalls of the recess, and not on a bottom portion of the sidewalls of the recess, due to the height-to-width aspect ratio of the recess (the sputtering-based deposition does not reach the bottom portion of the recess). In one embodiment, the sputtered liner layer has a bottom perimeter that is non-smooth, e.g., has irregularities (e.g., peaks and valleys) and is curvilinear. Subsequently, the dielectric material surrounding the bottom portion of the recess is at least partially etched through the recess. In particular, the etching process widens the bottom portion of the recess that is not protected by the liner layer, which now has a diameter of db. As discussed, the liner layer is etch selective to the dielectric material. Accordingly, the liner layer on the top portion of the recess, and the dielectric material underneath the liner layer, are not etched. Accordingly, the top portion is not widened, and has the original diameter of dt. Thus, the etching process selectively widens the bottom portion of the recess to have the diameter of db, while the top portion of the recess is not widened and still has the diameter of dt. In an example, the diameter db of the bottom portion is greater than the diameter dt of the top portion by at least 5%, or at least 10%, or at least 15%, or at least 20%, or at least 25%, or more. Subsequently, conductive material is deposited within the multi-diameter recess (or an otherwise multi-dimensional recess having a narrower top portion and a wider bottom portion), to form the interconnect feature. Note that the conductive material is deposited within the recess in a single deposition process, and hence, a monolithic body of conductive material is within the top portion of the recess, a middle portion of the recess, and the bottom portion of the recess. Thus, the resultant interconnect feature has a narrower top portion and a wider bottom portion. In an example, the interconnect feature also includes a middle portion between the top and bottom portions, wherein in the middle portion, the diameter dt of the top portion transitions to the diameter db of the bottom portion. In an example, the middle portion is an irregular tapered portion defined by an upper perimeter and a lower perimeter. The diameter dt of the top portion transitions to the diameter of the bottom portion along the irregular tapered middle portion of the interconnect feature. In an example, each of the upper and lower perimeters is not straight line, and is non-smooth and curvilinear (e.g., has irregularities), e.g., has peaks and valleys. In an example, the curvilinear upper and lower perimeters is due to, or otherwise track, the non-smooth and curvilinear bottom perimeter of the previously discussed liner layer formed by sputtering.

In another embodiment where the intermediate interconnect feature is formed using etch selectivity of two layers of dielectric materials, an upper layer comprising an upper dielectric material is formed over a lower layer comprising a lower dielectric material. The upper and lower dielectric materials are compositionally different and etch selective with respect to each other. Subsequently, a recess is formed within and through the upper and lower layers, where the recess has a diameter of dt. Thus, a top portion of the recess is within the upper layer, and a bottom portion of the recess is within the lower layer. Subsequently, the lower dielectric material adjacent to the bottom portion of the recess is in part etched through the recess, thereby widening the bottom portion of the recess. Note that due to the etch selectivity between the upper and lower dielectric materials, the upper dielectric material adjacent to the top portion of the recess is not substantially etched, and hence, the top portion of the recess still has the original diameter of dt. Thus, the bottom portion of the recess now has a diameter of db, which is greater than the diameter dt of the top portion. In an example, diameter db is greater than diameter dt by at least 5%, or at least 10%, or at least 15%, or at least 20%, or at least 25%, or more. Subsequently, conductive material is deposited within the recess, to form the multi-dimensional interconnect feature. Note that the conductive material is deposited within the recess in a single deposition process, and hence, a monolithic body of conductive material is within the top portion of the recess, a middle portion of the recess, and the bottom portion of the recess. Thus, the resultant interconnect feature has a narrower top portion and a wider bottom portion. In an example, the interconnect feature also includes a middle portion between the top and bottom portions, wherein in the middle portion, the diameter dt of the top portion transitions to the diameter db of the bottom portion. In an example, the middle portion is a tapered portion defined by an upper perimeter and a lower perimeter. Note that unlike the previously discussed scenario where the recess is selectively widened using a liner layer and where the upper and lower perimeters were irregular, in the case where the recess is selectively widened using the etch selectivity between the top and bottom dielectric materials, the upper and lower perimeters are substantially linear. For example, the upper perimeter of the middle portion is substantially coplanar with a junction between the upper and lower dielectric materials.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, in some embodiments, such tools may be used to detect an interconnect feature above a device layer, where the interconnect feature has a relatively narrow top portion and a relatively wide bottom portion. In some such embodiments, such tools may also be used to detect a middle portion of the interconnect feature between the top and bottom portions, where a diameter dt of the top portion transitions to a diameter db of the bottom portion in the middle portion, and where one or both of a top perimeter or a bottom perimeter of the middle portion is curvilinear. Numerous configurations and variations will be apparent in light of this disclosure.

### Architecture and Methodology

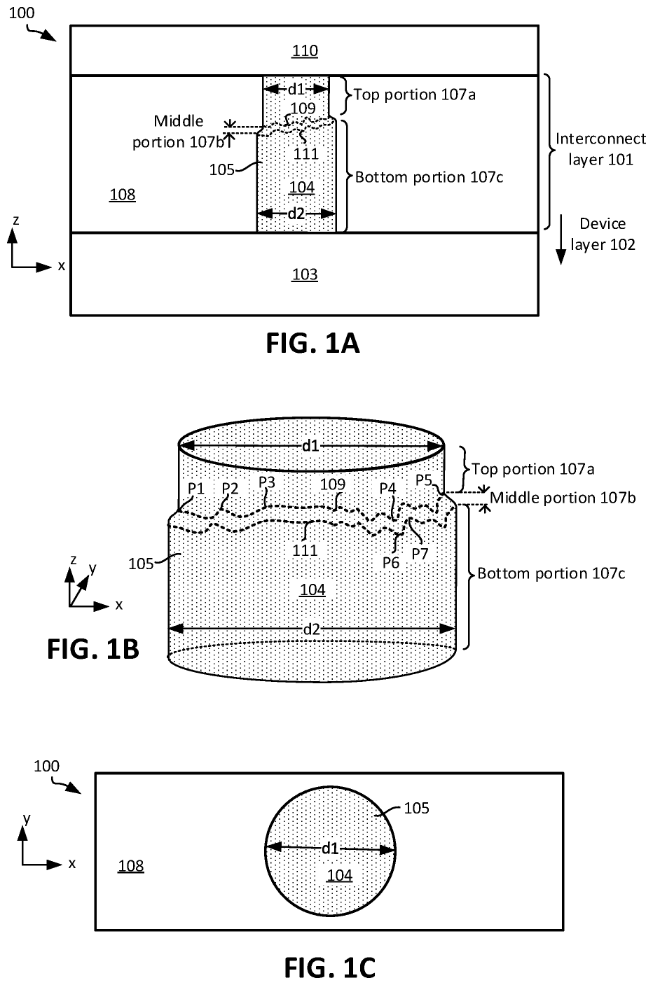

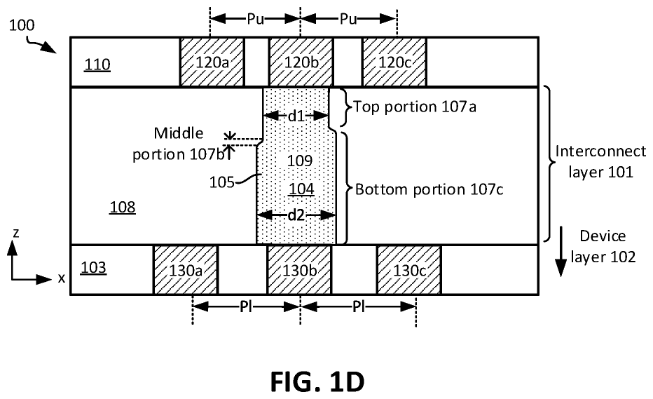

FIG. 1A illustrates a cross-sectional view of a section of an integrated circuit (IC) 100 comprising an interconnect layer 101 above a device layer 102 comprising a plurality of active devices, wherein the interconnect layer 101 comprises an interconnect feature 104 (e.g., a conductive via) within dielectric material 108, wherein the interconnect feature 104 has a relatively narrower top portion 107a and a relatively wider bottom portion 107c, and wherein the interconnect feature 104 comprises a monolithic body of conductive material 105 within both the top portion 107a and the bottom portion 107c, in accordance with an embodiment of the present disclosure. FIG. 1B illustrate a magnified perspective view of the interconnect feature 104 of FIG. 1A, in accordance with an embodiment of the present disclosure. FIG. 1C illustrates a plan view of the interconnect layer 101 including the interconnect feature 104, in accordance with an embodiment of the present disclosure.

As illustrated in FIG. 1A, the IC 100 comprises a layer 103, where the interconnect layer 101 is above the layer 103. In an example, the layer 103 may be a lower interconnect layer comprising a plurality of interconnect features within dielectric material of the lower interconnect layer. In another example, the layer 103 comprises a device layer 102 including one or more active and/or passive devices, such as transistors. Thus, the layer 103 is symbolic of any component(s) of the IC 100 below the interconnect layer 101.

As illustrated in FIG. 1A, a device layer 102 comprising one or more active and/or passive devices, such as transistors, is below the interconnect layer 101. As discussed, in one example, the device layer 102 may be the layer 103. In another example, the device layer 102 may be below the layer 103. However, irrespective of an actual location of the device layer 102, the device layer 102 is below the interconnect layer 101.

As illustrated in FIG. 1A, the IC 100 comprises a layer 110 above the interconnect layer 101. In an example, the layer 110 may be an upper interconnect layer comprising a plurality of interconnect features within dielectric material of the upper interconnect layer.

In one embodiment, the interconnect layer 101 comprises a layer of dielectric material 108, and a plurality of conductive interconnect features within the dielectric material 108. One such example conductive interconnect feature 104 of the interconnect layer 101 is illustrated in FIG. 1A, where the interconnect feature 104 of the interconnect layer 101 is within the dielectric material 108.

In one embodiment, the interconnect feature 104 is a conductive via extending within and through the dielectric material 108 of the interconnect layer 101. The interconnect feature 104 couples a conductive component (e.g., a transistor, or another interconnect feature such as a conductive line, not illustrated in FIG. 1A) of the layer 103 to another conductive component (e.g., another interconnect feature such as a conductive line, not illustrated in FIG. 1A) of the layer 110, as discussed herein later with respect to FIG. 1D, for example. For example, a top surface of the interconnect feature 104 is conductively coupled to a conductive component of the layer 110, and a bottom surface of the interconnect feature 104 is conductively coupled to another conductive component of the layer 103.

In one embodiment, the dielectric material 108 is an appropriate dielectric material, such as an Interlayer Dielectric (ILD) material, an oxide or nitride (such as silicon oxide or silicon nitride), oxocarbon, a dielectric material comprising an appropriate combination of silicon, nitrogen, oxygen, or carbon, or an appropriate low-k dielectric material generally used in interconnect layers.

As illustrated in FIGS. 1A and 1B, the interconnect feature 104 comprises a top portion 107a, a bottom portion 107c below the top portion 107a, and a middle portion 107b between the top portion 107a and the bottom portion 107c.

In one embodiment, the top portion 107a is narrower than the bottom portion 107c. In an example, a top surface of the interconnect feature 104 is narrower than a bottom surface of the interconnect feature 104. Thus, a diameter d1 of the top portion 107a is less than a diameter d2 of the bottom portion 107c. For example, the diameter d1 of the top portion 107a is less than the diameter d2 of the bottom portion 107c by at least 3%, at least 5%, or at least 10%, or at least 15%, or at least 20%, or at least 25%. Merely as an example and without limiting the scope of this disclosure, the diameter d1 may be in the range of 3 to 10 nanometers (nm), 10 to 25 nm, 10 to 100 nm, 0.1 micron to 1 micron, 0.1 micron to 5 microns, 1 micron to 10 microns, 5 microns to 10 microns, or 5 microns to 20 microns, and the diameter d2 is at least 3% higher, or at least 5% higher, or at least 10% higher, or at least 15% higher, or at least 20% higher, or at least 25% higher than the diameter d1. As illustrated, the diameters d1 and d2 are measured in a horizontal direction, which is perpendicular to a length of the interconnect feature 104. Note that the plan view of FIG. 1C illustrates a top surface of the top portion 107a and has the diameter d1.

As illustrated, in the middle portion 107b, the diameter d1 of the top portion 107a transitions to the diameter d2 of the bottom portion 107c. Thus, various sections of the middle portion 107b has a diameter that is in a range defined by the diameters d1 and d2.

Note that in some examples, the top portion 107a may be slightly tapered, based on an etch technology used to form a recess (e.g., recess 304 discussed herein later) for the interconnect feature, e.g., a bottom section of the top portion 107a may have a diameter that is slightly less than a diameter of a top section of the top portion 107a, although such slight tapering is not illustrated in FIGS. 1A and 1B. In some examples, the diameter of the top portion 107a may vary slightly along a length of the top portion 107a, e.g., due to slight irregularities in the cylindrical shape of the top portion. In some examples, the diameter d1 may be an average diameter of the top section 107a, where the averaging is performed along a length of the top section 107a.

Note that in some examples, the bottom portion 107c may be slightly tapered, based on an etch technology used to form a recess (e.g., recess 304 discussed herein later) for the interconnect feature and an etching process to widen the bottom portion 107c, although such slight tapering is not illustrated in FIGS. 1A and 1B. In some examples, the diameter of the bottom portion 107c may vary slightly along a length of the bottom portion 107c, e.g., due to slight irregularities in the cylindrical shape of the bottom portion. In some examples, the diameter d2 may be an average diameter of the bottom section 107c, where the averaging is performed along a length of the bottom section 107c.

Illustrated in FIGS. 1A and 1B is an imaginary dotted line 109, which is an upper perimeter of the middle portion 107a and is an interface between the top portion 107a and middle portion 107b. Also illustrated is an imaginary dotted line 111, which is a lower perimeter of the middle portion 107a and is an interface between the middle portion 107b and bottom portion 107c. As illustrated, the middle portion 107b is an irregular tapered portion defined by the upper perimeter 109 and the lower perimeter 111. The diameter d1 of the top portion 107a transitions to the diameter d2 of the bottom portion 107c along the irregular tapered middle portion 107b of the interconnect feature 104.

Example points P1, P2, P3, P4, and P5 are on the upper perimeter 109. For example, when traversing from the top surface to the bottom surface of the interconnect feature 104, from each point on the interface 109, the interconnect feature 104 starts getting wider. Thus, a section of the interconnect feature 104 below the point P1 is wider than a section of the interconnect feature above the point P1; a section of the interconnect feature 104 below the point P2 is wider than a section of the interconnect feature above the point P2; a section of the interconnect feature 104 below the point P3 is wider than a section of the interconnect feature above the point P3; and so on.

As illustrated, each of the perimeters 109 and 111 is not straight line, and is non-smooth and curvilinear (e.g., has irregularities), e.g., has peaks and valleys. Merely as an example, points P1 and P4 in FIG. 1B is at a lower level than the point P5. Thus, a first distance between the point P5 and the top surface of the interconnect feature 104 is shorter than a second distance between the point P4 and the top surface of the interconnect feature 104. For example, the first distance is shorter than the second distance by at least 1 angstrom, or by at least 5 angstroms, or by at least 10 angstroms, or by at least 25 angstroms.

Similarly, as illustrated in FIG. 1B, points P6 and P7 are on the lower perimeter 111, and point P6 is at a lower level than the point P7. Thus, a third distance between the point P7 and the top surface of the interconnect feature 104 is shorter than a fourth distance between the point P6 and the top surface of the interconnect feature 104. For example, the third distance is shorter than the fourth distance by at least 1 angstrom, or by at least 5 angstroms, or by at least 10 angstroms, or by at least 25 angstroms.

Thus, the diameter d1 of the top portion 107a starts transitioning to the diameter d2 of the bottom portion 107c along the upper perimeter 109 that spans a perimeter of the interconnect feature 104, wherein the upper perimeter 109 is non-smooth and has peaks and valleys. Similarly, the lower perimeter 111 of the middle portion 107b is also non-smooth, e.g., has peaks and valleys. In an example, the perimeters 109, 111 are non-smooth due to a process used to widen the bottom portion 107c, as will be discussed herein in further detail.

As illustrated, in an example, the middle portion 107b has a smaller height relative to a height of the top portion 107a or a height of the bottom portion 107c. For example, the middle portion 107b has a vertical height that is at most 10%, or at most 8%, or at most 5%, or at most 3%, or at most 2%, or at most 1% of the total vertical height of the interconnect feature 104.

In another example, the middle portion 107b has a substantially zero height (e.g., a height less than 1% of the total height of the interconnect feature 104, and/or a height that is at most 1 nm), and in such an example, the interfaces 111 and 109 coincides, such that there is a substantial step transition of the diameter d1 to the diameter d2, rather than a less abrupt or tapered transition as explained above.

In one embodiment, a height of the top portion 107a is less than a height of the bottom portion 107b. For example, the height of the top portion 107a is at most 95%, or at most 90%, or at most 80%, or at most 75%, or at most 60%, or at most 50%, or at most 40%, or at most 30%, or at most 20% of the height of the bottom portion 107b.

In one embodiment, the interconnect feature 104 comprises conductive material 105. The conductive material 105 is deposited in the top portion 107a in a same deposition process, the middle portion 107b, and the bottom portion 107c. Accordingly, the conductive material 105 within the top portion 107a, the middle portion 107b, and the bottom portion 107c comprises a monolithic body of conductive material. For example, the conductive material within the top portion 107a and the conductive material within the middle portion 107b does not have any seam, grain boundary, liner or barrier layer, or interface therebetween; and similarly, the conductive material within the middle portion 107b and the conductive material within the bottom portion 107c does not have any seam, grain boundary, liner or barrier layer, or interface therebetween.

In one embodiment, the conductive material 105 within the interconnect feature 104 may comprise any appropriate conductive material used for interconnect features, such as copper, ruthenium, molybdenum, cobalt, tungsten, an alloy such as copper-tin (CuSn), copper indium (CuIn), copper-antimony (CuSb), copper-bismuth (CuBi), copper-rhenium (CuRe), and/or any other suitable conductive material.

Although not illustrated in FIGS. 1A-1C, in an example, a liner or barrier layer is on walls of the interconnect feature 104, e.g., between the conductive material 105 of the interconnect feature 104 and the dielectric material 108. In an example, such a liner or barrier layer facilitates better adhesion of the conductive material 105 of the interconnect feature 104 to the walls of the dielectric material 108, and/or prevents or reduces diffusion of the conductive material 105 of the interconnect feature 104 to adjacent dielectric material 108. Suitable materials for the linear or barrier layer include refractory metals and alloys, cobalt, cobalt-nickel (CoNi), ruthenium-cobalt combination, molybdenum, nickel, manganese, titanium-tungsten (Ti), tantalum (Ta), tantalum-nitride (TaN), tantalum-silicon-nitride (TaSiN), titanium-nitride (TiN), titanium-silicon-nitride (TiSiN), tungsten (XV), tungsten-nitride (WN), tungsten-silicon-nitride (WiSiN), and/or combinations of such materials (e.g., a multi-lay stack of Ta/TaN). However, in another example, the interconnect feature 104 lacks any such liner or barrier layer.

FIG. 1D illustrates the interconnect layer 101 of FIGS. 1A-1C between (i) an upper interconnect layer 110 comprising a plurality of upper conductive features 120a, 120b, 120c arranged at a first pitch Pu and (ii) a lower layer 103 comprising a plurality of lower conductive features 120a, 120b, 120c arranged at a second pitch P1 that is higher than the first pitch Pu, wherein the interconnect feature 104 of the interconnect layer 101 of FIGS. 1A-1C conductively couple one of the upper conductive features to one of the lower conductive features, in accordance with an embodiment of the present disclosure.

In an example, the upper conductive features 120a, 120b, 120c are conductive interconnect features, such as conductive lines. In an example, the lower conductive features 130a, 130b, 130c are conductive interconnect features, such as conductive lines. In another example, the lower conductive features 130a, 130b, 130c are contacts (e.g., source contact, drain contact, and/or gate contacts) of one or more active devices, such as transistor devices.

As illustrated, the conductive features 120 are at a pitch Pu, and the conductive features 130 are at a pitch P1. In one embodiment, the pitch Pu is less than the pitch P1. Accordingly, if the top portion 107a of the interconnect feature 104 had the wider diameter d2, this would have increased chances of electrical shorting between the interconnect feature 104 and the conductive feature 120a (or the conductive feature 120c). However, as the diameter d1 of the top portion 107a is relatively less (e.g., compared to the diameter d2), this increases lateral distance between the interconnect feature 104 and the conductive feature 120a and/or increases lateral distance between the interconnect feature 104 and the conductive feature 120c (e.g., compared to a situation where the top portion 107a also had the wider diameter of d2).

However, as the pitch P1 is higher, the bottom portion 107c may be made wider, without significantly increasing chances of electrical shorting between the interconnect feature 104 and the conductive feature 130a (or the conductive feature 130c). Furthermore, the wider diameter d2 of the bottom portion 107c decreases contact resistance between the interconnect feature 104 and the conductive feature 130b.

Thus, the interconnect feature 104 has the unique profile of being relatively narrow at a top surface of the interconnect feature 104, and relatively wide at a bottom surface of the interconnect feature 104. The narrow top surface reduces chances of unintended electrical shorting between the interconnect feature 104 and the conductive feature 130a (or conductive feature 130c), and the wide bottom surface reduces contact resistance between the interconnect feature 104 and the conductive feature 130b.

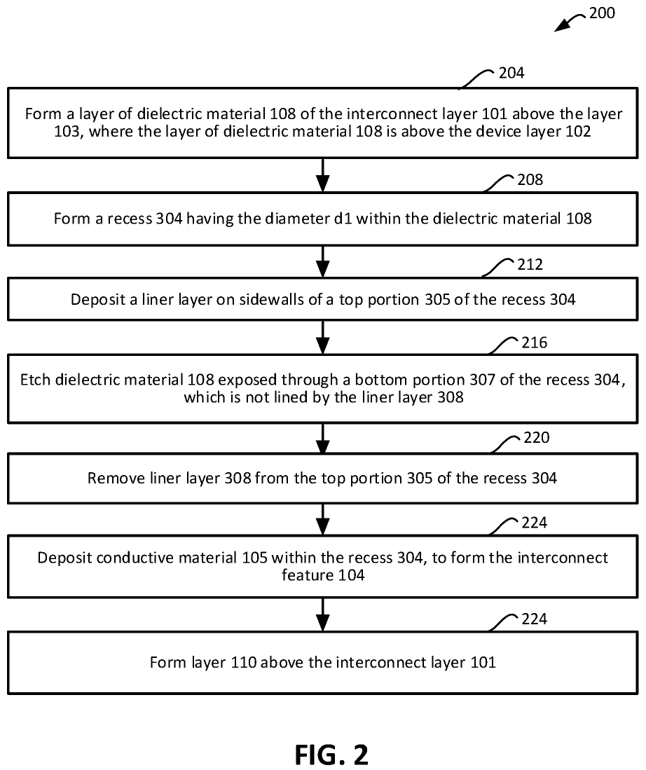

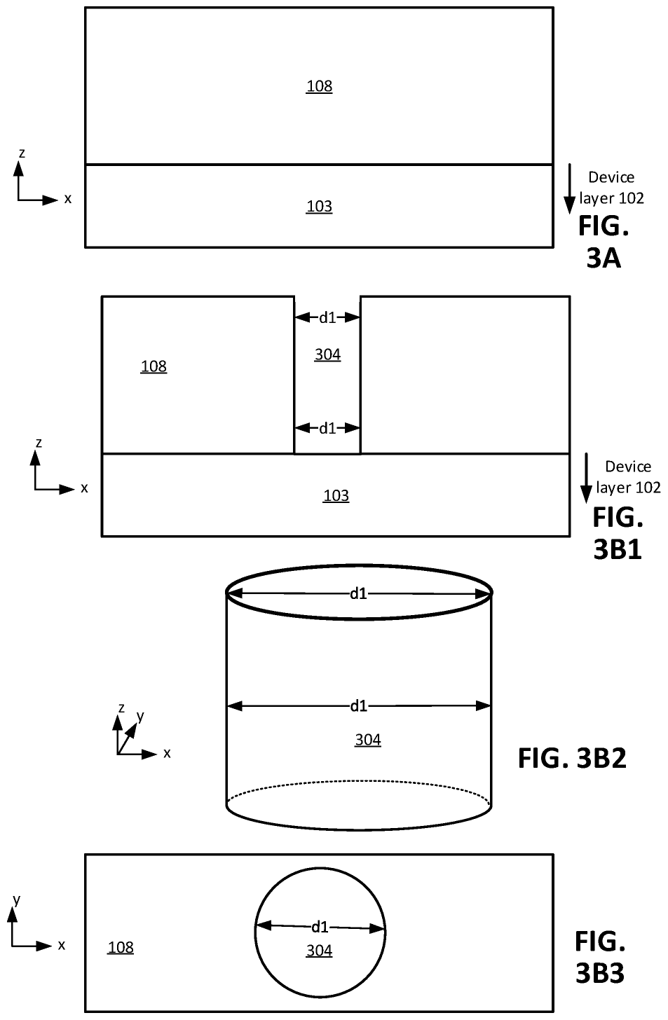

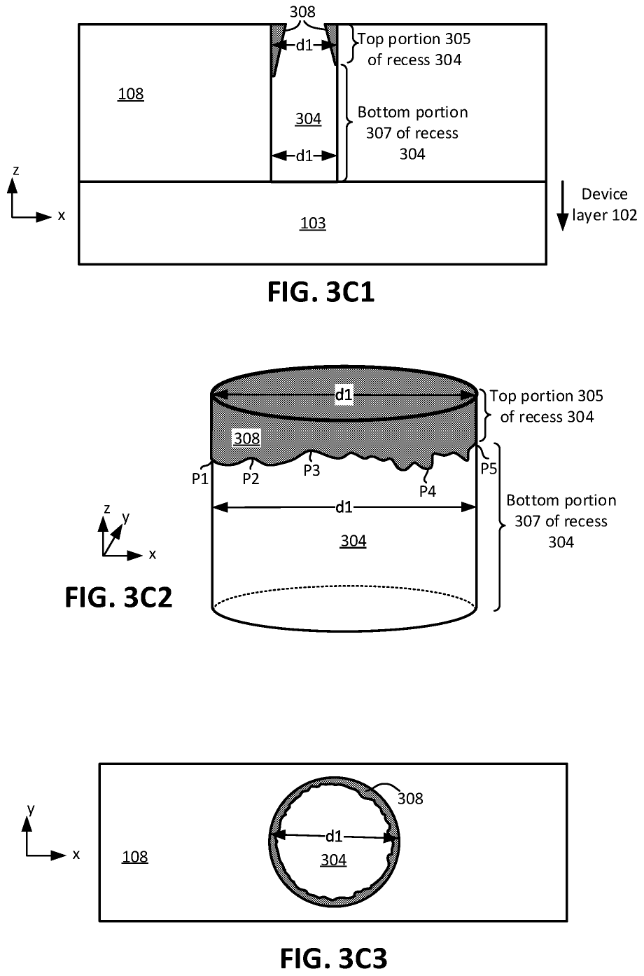

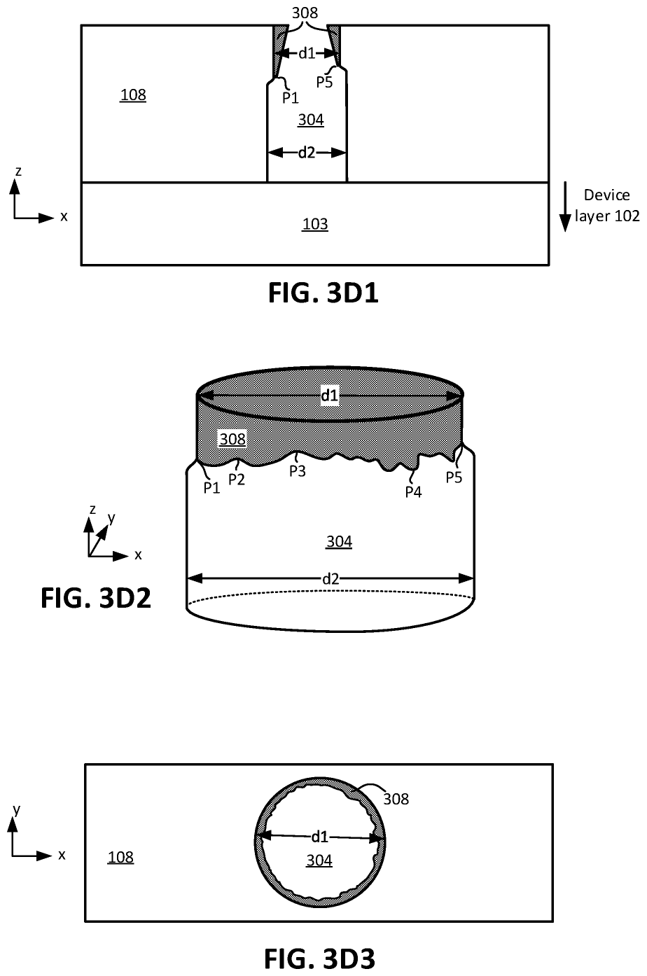

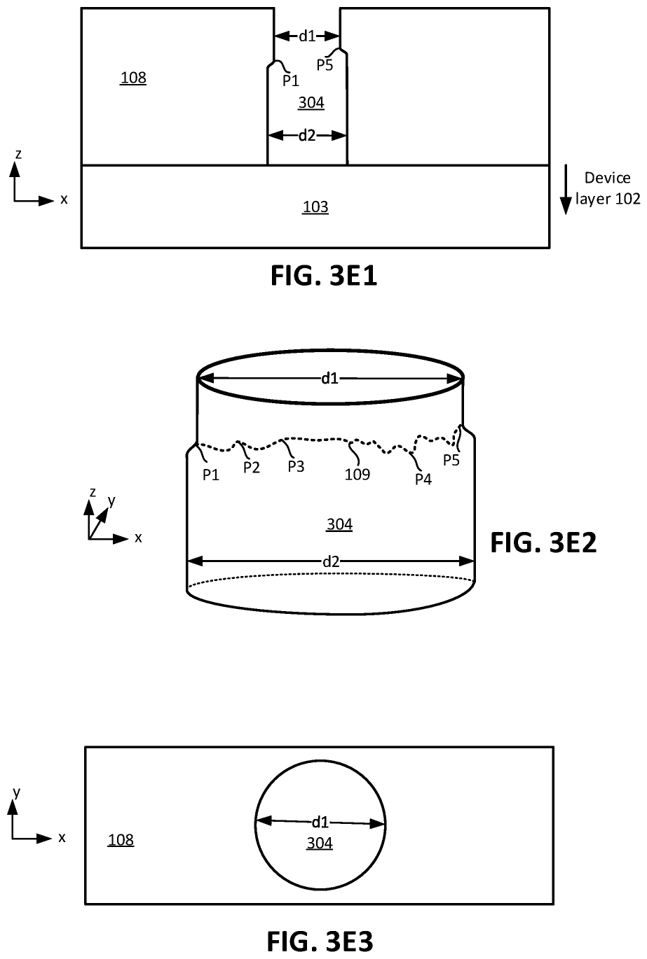

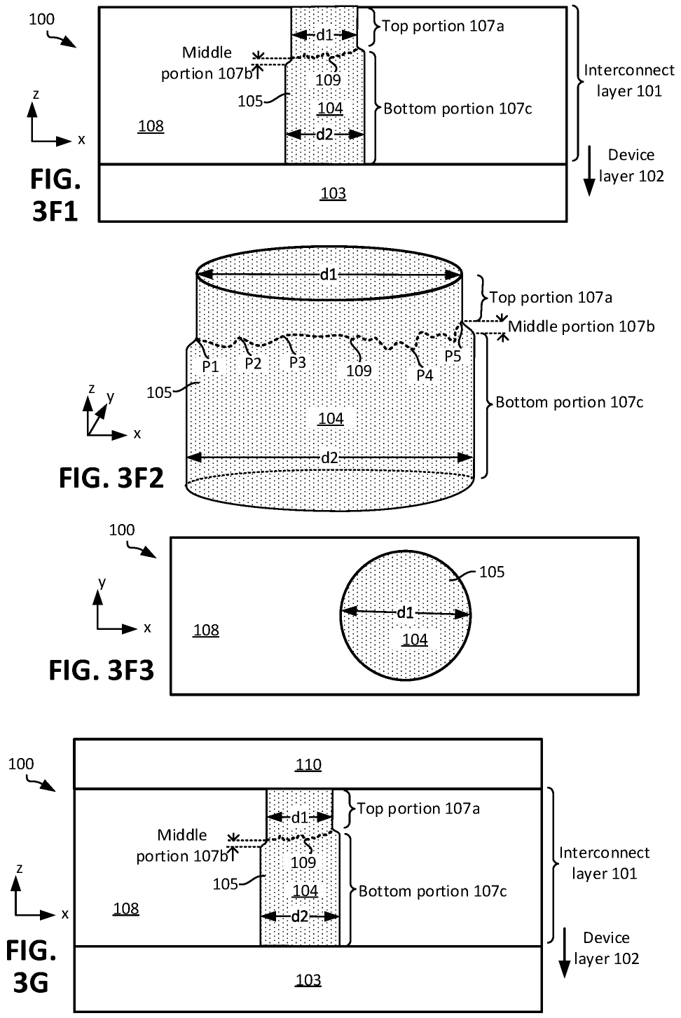

FIG. 2 illustrates a flowchart depicting a method 200 of forming an IC (such as the IC 100 of FIGS. 1A-1C) comprising an interconnect layer 101 above a device layer 102 comprising a plurality of active devices, wherein the interconnect layer 101 comprises an interconnect feature 104 (e.g., a conductive via) that has a relatively narrower top portion and a relatively wider bottom portion, and wherein the interconnect feature comprises a monolithic body of conductive material 105 within both the top portion and the bottom portion, in accordance with an embodiment of the present disclosure. FIGS. 3A, 3B1, 3B2, 3B3, 3C1, 3C2, 3C3, 3D1, 3D2, 3D3, 3E1, 3E2, 3E3, 3F1, 3F2, 3F3, and 3G illustrate various views of an IC (such as the IC 100 of FIGS. 1A, 1B, and 1C) in various stages of processing, in accordance with an embodiment of the present disclosure. FIGS. 2 and 3A-3G will be discussed in unison.

FIGS. 3A, 3B1, 3C1, 3D1, 3E1, 3F1, and 3G illustrate cross-sectional views of the IC 100 (e.g., similar to the view of FIG. 1A), as the IC 100 is being formed. FIGS. 3B2, 3C2, 3D2, 3E2, and 3F2 illustrate magnified perspective views of a recess 304 and subsequent perspective views of the interconnect feature 104 formed within the recess 304 (e.g., similar to the view of FIG. 1B), as the IC 100 is being formed. FIGS. 3B3, 3C3, 3D3, 3E3, and 3F3 illustrate plan views of the dielectric material 108 and the recess 304, and subsequent plan views of the dielectric material 108 and the interconnect feature 104 formed within the recess 304 (e.g., similar to the view of FIG. 1C), as the IC 100 is being formed.

Referring to FIG. 2, the method 200 includes, at 204, forming a layer of dielectric material 108 of the interconnect layer 101 above the layer 103, as also illustrated in FIG. 3A. As previously discussed herein, the device layer 102 is either the layer 103, or is below the layer 103. Thus, the layer of dielectric material 108 is above the device layer 102.

Referring again to FIG. 2, the method 200 then proceeds from 204 to 208, where a recess 304 having the diameter d1 is formed within the dielectric material 108. For example, FIG. 3B1 illustrates the dielectric material 108, with the recess 304 formed therewithin. FIG. 3B2 illustrates a magnified perspective view of the recess 304. In the example of FIG. 3B2, the recess 304 has a shape of a cylinder, although the recess 304 can have another appropriate 3-dimensional shape, such as a cube. FIG. 3B3 illustrates a plan view of the recess 304. In an example, the recess 304 may be formed within the dielectric material 108 using suitable masking, lithography, and etching technique, such as an anisotropic etch process. Note that the recess 304 may be slightly tapered, based on an etch technology used to form the recess 304, e.g., a bottom section may have a diameter that is slightly less than a diameter of a top section, although such slight tapering is not illustrated in FIGS. 3B1, 3B2.

Referring again to FIG. 2, the method 200 then proceeds from 208 to 212, where a liner layer 308 is deposited on sidewalls of a top portion 305 of the recess 304, as illustrated in FIGS. 3C1, 3C2, and 3C2. In an example, the liner layer 308 may be deposited using an appropriate deposition technique. Merely as an example, the liner layer 308 may be deposited using sputtering, where the liner layer 308 coats inner sidewalls of the top portion 305 of the dielectric material 108.

In an example, the liner layer 308 is relatively thickly deposited near the top surface, and a thickness of the liner layer 308 may gradually decrease towards a bottom section of the top portion 305 of the recess 304, as illustrated in FIG. 3C1. The sputtering process is based on a line-of-visibility, and the top portion 305 of the recess 304 visible to the sputtering tools are lined with the liner layer. As the bottom portion 307 is not visible to the sputtering tools, the bottom portion 307 of the recess 304 may not be substantially lined with the liner layer 308, as illustrated in FIGS. 3C1 and 3C2.

In an example where sputtering is used to deposit the liner layer 308, the bottom perimeter of the liner layer 308 is non-smooth due to the sputtering process used to deposit the liner layer 308, as illustrated in FIG. 3C2. An interface between the top and bottom portions 305, 307 of the recess 304 is non-smooth, and has peaks and valleys. For example, points P1, P2, P3, P4, and P4 are on the interface between the top and bottom portions 305, 307 of the recess 304, where the interface is a non-smooth curvilinear line having peaks and valleys. FIG. 3C3 illustrates a plan view of the liner layer 308. As seen, in an example, a thickness of the liner layer 308 may also vary along a periphery of the recess 304.

In one embodiment, the liner layer 308 is etch selective to the dielectric material 108. For example, an etch process (discussed herein later with respect to process 216) that etches the dielectric material 108 may not substantially etch the liner layer 308. Thus, the dielectric material 108 and the liner layer 308 are compositionally different. In an example, the liner layer 308 comprises titanium oxide, titanium nitride, and/or other suitable material that is etch selective to the dielectric material 108 and that can be deposited using sputtering.

Referring again to FIG. 2, the method 200 then proceeds from 212 to 216, where the dielectric material 108 exposed through the bottom portion 307 of the recess 108 (e.g., sections of the dielectric material 108 that are not lined by the liner layer 308) are etched. For example, the etchants enter the recess 304 though the top portion 305 of the recess 304. An appropriate isotropic etch process may be employed in the process 216. The liner layer 308 protects the dielectric material 108 adjacent to the top portion 305 of the recess 304 from being etched, e.g., as the liner layer 308 is etch selective to the dielectric material 108. As the liner layer 308 is not on the bottom portion 307, the dielectric material 108 adjacent to the bottom portion 305 of the recess 304 is etched away. This results in the bottom portion 307 of the recess becoming wider relative to the top portion 305 of the recess, as illustrated in FIGS. 3D1, 3D2, 3D3. For example, the bottom portion 307 now has a width d2, which is greater than the width d1.

As discussed with respect to FIGS. 1A and 1B and as also illustrated in FIG. 3D2, a middle portion of the recess 308, which is now between the top (or un-etched) portion of the recess 308 and the bottom portion of the recess, has top and bottom edges that are non-smooth, e.g., has peaks and valleys, e.g., due to the bottom perimeter of the liner layer 308 being non-smooth.

Referring again to FIG. 2, the method 200 then proceeds from 216 to 220, where the liner layer 308 is removed from the top portion 305 of the recess 304, as illustrated in FIG. 3E1, 3E2, and 3E3. An appropriate etch process may be employed in the process 216, such as an isotropic etch process. Again, as the liner layer 308 and the dielectric material 108 are etch selective with respect to each other, the dielectric material 108 is not substantially removed during the process 220.

Referring again to FIG. 2, the method 200 then proceeds from 220 to 224, where conductive material 105 is deposited within the recess 304, to form the interconnect feature 104, as also illustrated in FIGS. 3F1, 3F2, and 3F3. As the conductive material 105 is deposited within the entire recess 304 using a single deposition process, no seam, interface, liner or barrier layer, or grain boundary is formed between the top and middle portions of the interconnect feature 104, or between the middle and bottom portions of the interconnect feature 104, as also discussed with respect to FIGS. 1A-1C. This completes formation of the interconnect layer 101 comprising the dielectric material 108, and the interconnect feature 104 extending within the dielectric material 108.

Referring again to FIG. 2, the method 200 then proceeds from 224 to 228, where layer 110 is formed above the interconnect layer 101, as also illustrated in FIG. 3G. In an example, the layer 110 is an interconnect layer, and is formed using techniques to form an interconnect layer. Thus, in IC 100 in FIG. 3G is similar to the IC 100 of FIGS. 1A-1C.

Note that the processes in method 200 are shown in a particular order for ease of description. However, one or more of the processes may be performed in a different order or may not be performed at all (and thus be optional), in accordance with some embodiments. Numerous variations on method 200 and the techniques described herein will be apparent in light of this disclosure.

Note that FIGS. 2 and 3E1-3E3 illustrate removal of the liner layer 308. However, in another embodiment, the liner layer 308 may not be removed (or may not be substantially or fully removed) from the recess 304, and the process 220 of FIG. 2 may be skipped (or may not be fully completed). In such an example, at process 224 of FIG. 2, the conductive material 105 may be deposited within the recess 304, where the recess 304 includes the liner layer 308 (or at least remnants of the liner layer 308, such as one or more possibly discontinuous monolayers of the liner layer 308). In such an example, the liner layer 308 (or at least remnants of the liner layer 308, such as one or more possibly discontinuous monolayers of the liner layer 308) may be present between the conductive material 105 of the interconnect feature 104 and the adjacent dielectric material 108.

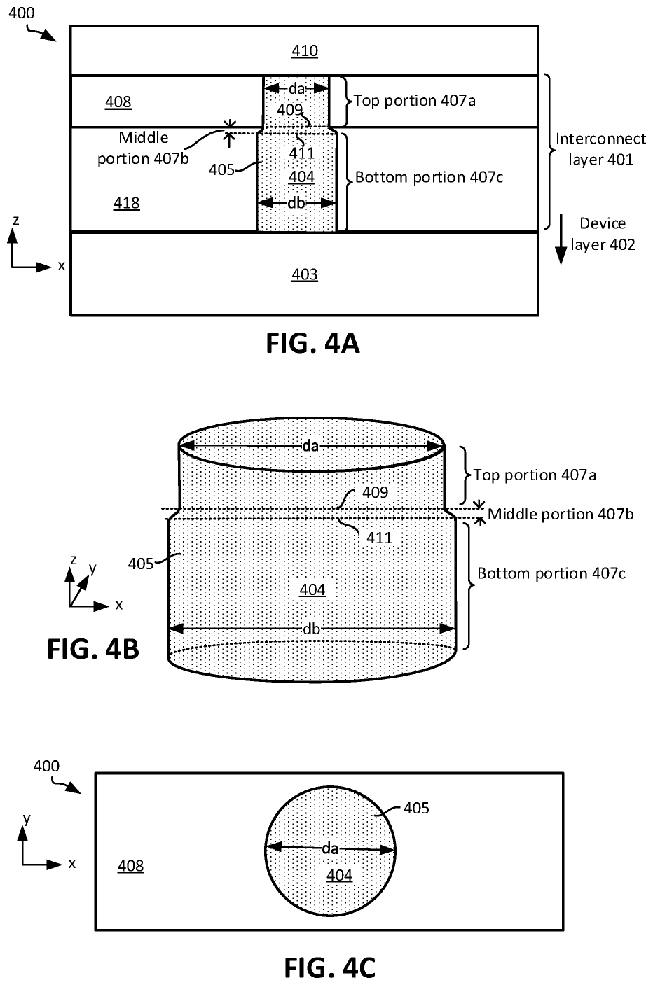

FIG. 4A illustrates a cross-sectional view of a section of an IC 400 comprising an interconnect layer 401 above a device layer 402 comprising a plurality of active devices, wherein the interconnect layer 401 comprises an interconnect feature 404 (e.g., a conductive via) that has (i) a relatively narrower top portion 407a within a top dielectric material 408, and (ii) a relatively wider bottom portion 407c within a bottom dielectric material 418, and wherein the interconnect feature 404 comprises a monolithic body of conductive material 405 within both the top portion 407a and the bottom portion 407c, in accordance with an embodiment of the present disclosure. FIG. 4B illustrate a magnified perspective view of the interconnect feature 404 of FIG. 4A, in accordance with an embodiment of the present disclosure. FIG. 4C illustrates a plan view of the interconnect layer 401 including the interconnect feature 404, in accordance with an embodiment of the present disclosure.

As illustrated in FIG. 4A, the IC 100 comprises a layer 403, where the interconnect layer 401 is above the layer 403. In an example, the layer 403 may be an interconnect layer comprising a plurality of interconnect features within dielectric material of the interconnect layer. In an example, the layer 403 comprises a device layer 402 comprising one or more active and/or passive devices, such as transistors. Thus, the layer 403 is symbolic of any component(s) of the IC 400 below the interconnect layer 401.

As illustrated in FIG. 4A, a device layer 402 comprising one or more active and/or passive devices, such as transistors, is below the interconnect layer 401. As discussed, in one example, the device layer 402 may be the layer 403. In another example, the device layer 402 may be below the layer 403. However, irrespective of an actual location of the device layer 402, the device layer 402 is below the interconnect layer 401.

As illustrated in FIG. 4A, the IC 400 comprises a layer 410 above the interconnect layer 401. In an example, the layer 410 may be an interconnect layer comprising a plurality of interconnect features within dielectric material of the interconnect layer.

In one embodiment, the interconnect layer 401 comprises a top layer of dielectric material 408, and a bottom layer of dielectric material 418 that is below the top layer of dielectric material 408. In one embodiment, the interconnect layer 401 also comprises a plurality of conductive interconnect features extending within and through the dielectric materials 408, 418. One such example conductive interconnect feature 404 of the interconnect layer 401 is illustrated in FIG. 4A, where the interconnect feature 404 of the interconnect layer 401 extends within and through the dielectric materials 408, 418.

In one embodiment, the interconnect feature 404 is a conductive via extending through the dielectric materials 408 and 418 of the interconnect layer 401. The interconnect feature 404 couples a conductive component (e.g., a transistor, or another interconnect feature such as a conductive line, not illustrated in FIG. 4A) of the layer 403 to another conductive component (e.g., another interconnect feature such as a conductive line, not illustrated in FIG. 4A) of the layer 410, e.g., similar to the discussion with respect to FIG. 1D. For example, a top surface of the interconnect feature 404 is conductively coupled to a conductive component of the layer 410, and a bottom surface of the interconnect feature 404 is conductively coupled to another conductive component of the layer 403.

In one embodiment, the dielectric materials 408 and 418 are appropriate dielectric materials, such as an Interlayer Dielectric (ILD) material, an oxide or nitride (such as silicon oxide or silicon nitride), oxocarbon, a dielectric material comprising an appropriate combination of silicon, nitrogen, oxygen, or carbon, or an appropriate low-k dielectric material used in interconnect layers. In an example, the dielectric materials 408 and 418 are compositionally different, and are etch selective with respect to each other. For example, an etch process to etch the dielectric material 418 may not substantially etch the dielectric material 408. Merely as an example, the top dielectric material 408 may be one of silicon nitride or silicon oxide, and the bottom dielectric material 418 may be another one of silicon nitride or silicon oxide, although any other combinations may also be possible.

As illustrated in FIGS. 4A and 4B, the interconnect feature 404 comprises (i) a top portion 407a within the dielectric material 408, (i) a bottom portion 407c below the top portion 407a, where the bottom portion 407c is within the dielectric material 418, and (iii) a middle portion 407b between the top portion 407a and the bottom portion 407c, where the middle portion 407b is within the dielectric material 418.

In one embodiment, the top portion 407a is narrower than the bottom portion 407c. In one embodiment, a diameter da of the top portion 407a is less than a diameter db of the bottom portion 407c. For example, the diameter da of the top portion 407a is less than the diameter db of the bottom portion 407c by at least 3%, or at least 5%, or at least 10%, or at least 15%, or at least 20%, or at least 25%. Merely as an example and without limiting the scope of this disclosure, the diameter da may be in the range of 3 to 10 nm, 10 to 25 nm, 10 to 100 nm, 0.1 micron to 1 micron, 0.1 micron to 5 microns, 1 micron to 10 microns, 5 microns to 10 microns, or 5 microns to 20 microns, and the diameter db may be at least 3% higher, or at least 5% higher, or at least 10% higher, or at least 15% higher, or at least 20% higher, or at least 25% higher than the diameter da. As illustrated, the diameters da and db are measured in a horizontal direction, which is perpendicular to a length of the interconnect feature 404. Note that the plan view of FIG. 4C illustrates a top surface of the top portion 407a and has the diameter da.

As illustrated, in the middle portion 407b, the diameter da of the top portion 407a transitions to the diameter da of the bottom portion 407c. Thus, various sections of the middle portion 407b has a diameter that is in a range defined by the diameters da and db. That is, the middle portion 407b is tapered from a top diameter of d1 to a bottom diameter of db.

Illustrated in FIGS. 4A and 4B is an imaginary dotted line 409, which is an interface between the top portion 407a and middle portion 407b; and another imaginary dotted line 411, which is an interface between the middle portion 407b and bottom portion 407c. As illustrated in FIGS. 4A and 4B (and contrary to the illustration of FIGS. 1A-1B), each of the interfaces 409 and 411 is substantially smooth or linear.

As illustrates, the interface 409 between the top portion 407a and the middle portion 407b coincides (e.g., is coplanar) with a junction between the dielectric materials 408 and 418. Thus, when traversing from top to bottom, the top portion 407a of the interconnect feature 404 is substantially entirely within the dielectric material 408; and the middle and bottom portions 407b, 407c of the interconnect feature 404 are substantially entirely within the dielectric material 418.

As illustrated, the middle portion 407b has a smaller height relative to a height of the top portion 407a or a height of the bottom portion 407c. For example, the middle portion 407b has a vertical height that is at most 10%, or at most 8%, or at most 5%, or at most 3%, or at most 2%, or at most 1% of the total vertical height of the interconnect feature 404. In an example, the middle portion 407b has a substantially zero height (e.g., a height less than 1% of the total height of the interconnect feature 404, and/or a height that is at most 1 nm), and in such an example, the interfaces 411 and 409 coincides, such that there is a relatively abrupt step transition of the diameter da to the diameter db, rather than a tapered transition.

In one embodiment, the interconnect feature 404 comprises conductive material 405. The conductive material 405 is deposited in a same deposition process in the top portion 407a, the middle portion 407b, and the bottom portion 407c. Accordingly, a monolithic body of conductive material 405 is within the top portion 407a, the middle portion 407b, and the bottom portion 407c. For example, the conductive material within the top portion 407a and the conductive material within the middle portion 407b does not have any seam, grain boundary, liner or barrier layer, or interface therebetween; and similarly, the conductive material within the middle portion 407b and the conductive material within the bottom portion 407c does not have any seam, grain boundary, liner or barrier layer, or interface therebetween.

In one embodiment, the conductive material 405 within the interconnect feature 404 may comprise any appropriate conductive material used for interconnect features, such as copper, ruthenium, molybdenum, cobalt, tungsten, an alloy such as copper-tin (CuSn), copper indium (CuIn), copper-antimony (CuSb), copper-bismuth (CuBi), copper-rhenium (CuRe), and/or any other suitable conductive material.

Although not illustrated in FIGS. 4A-4C, in an example, a liner or barrier layer is on walls of the interconnect feature 404, e.g., between the conductive material 405 of the interconnect feature 404 and the dielectric materials 408, 418, e.g., as also discussed with respect to FIGS. 1A-1C.

The interconnect feature 404 has the unique profile of being relatively narrow at a top surface of the interconnect feature 404, and relatively wide at a bottom surface of the interconnect feature 404. In an example, and similar to the discussion with respect to FIG. 1D, the narrow top surface of the interconnect feature 404 reduces chances of unintended electrical shorting between the interconnect feature 404 and conductive features of the layer 410, and the wide bottom surface reduces contact resistance between the interconnect feature 404 and a conductive feature of the layer 403.

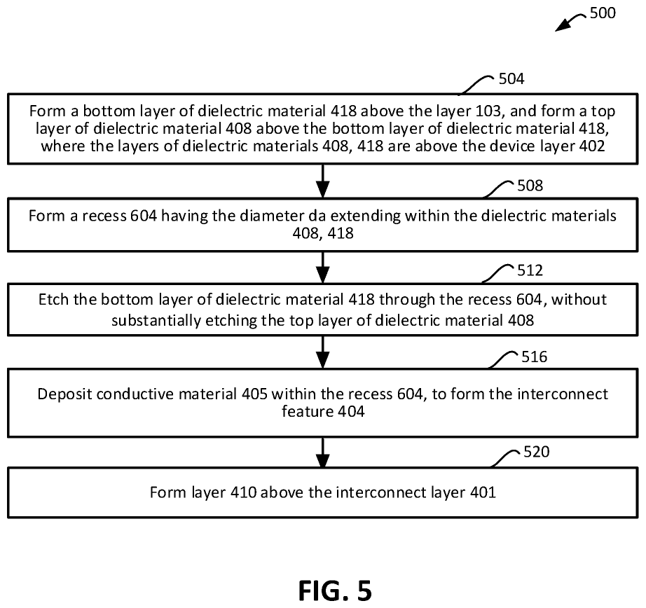

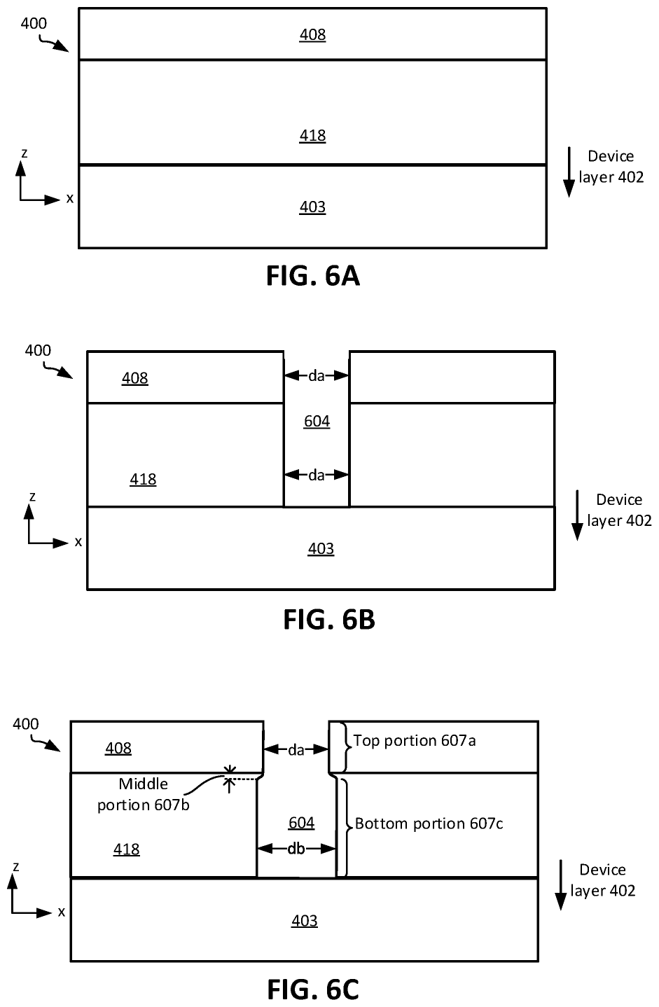

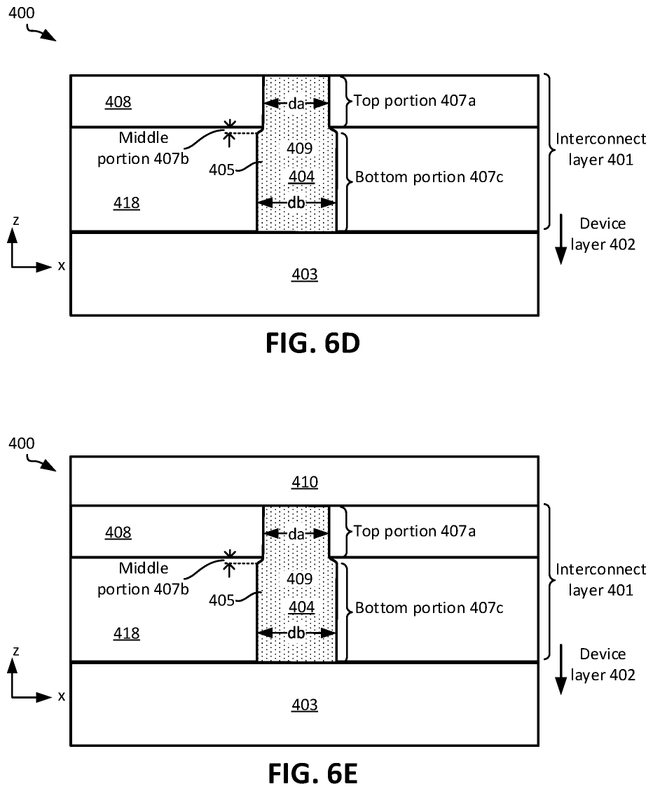

FIG. 5 illustrates a flowchart depicting a method 500 of forming an IC (such as the IC 400 of FIGS. 4A-4C) comprising an interconnect layer 401 above a device layer 402 comprising a plurality of active devices, wherein the interconnect layer 401 comprises an interconnect feature 404 (e.g., a conductive via) that has (i) a relatively narrower top portion 407a within a top dielectric material 408, and (ii) a relatively wider bottom portion 407c within a bottom dielectric material 418, and wherein the interconnect feature 404 comprises a monolithic body of conductive material 405 within both the top portion 407a and the bottom portion 407c, in accordance with an embodiment of the present disclosure. FIGS. 6A, 6B, 6C, 6D, and 6E illustrate cross-sectional views of an IC (such as the IC 400 of FIGS. 4A, 4B, and 4C) in various stages of processing, in accordance with an embodiment of the present disclosure. FIGS. 5 and 6A-6E will be discussed in unison.

Referring to FIG. 5, the method 500 includes, at 504, forming a bottom layer of dielectric material 418 of the interconnect layer 401 above the layer 403, and forming a top layer of dielectric material 408 of the interconnect layer 401 above the bottom layer of dielectric material 418, as also illustrated in FIG. 6A. As previously discussed herein, the device layer 402 is either the layer 403, or is below the layer 403. Thus, the layers of dielectric materials 408, 418 are above the device layer 402.

As discussed herein previously, the dielectric materials 408 and 418 are compositionally different, and are etch selective with respect to each other. For example, an etch process to etch the dielectric material 418 may not substantially etch the dielectric material 408. Merely as an example, the top dielectric material 408 may be one of silicon nitride or silicon oxide, and the bottom dielectric material 418 may be another one of silicon nitride or silicon oxide, although any other combinations may also be possible.

Referring again to FIG. 5, the method 500 then proceeds from 504 to 508, where a recess 604 having the diameter da is formed within the dielectric materials 408, 418. For example, FIG. 6B illustrates the recess 604 extending within and through the layers of dielectric materials 408, 418. In an example, the recess 604 may be formed within the dielectric materials 408, 418 using suitable masking, lithography, and etching technique, such as an anisotropic etch process. For example, a first etch process may form a bottom section of the recess 604 within the dielectric material 418, and a subsequent second etch process may form a top section of the recess 604 within the dielectric material 408.

Referring again to FIG. 5, the method 500 then proceeds from 508 to 512, where the bottom layer of dielectric material 418 is etched through the recess 604, without substantially etching the top layer of dielectric material 408. This results in a bottom portion 607c of the recess 604 (e.g., which is within the dielectric material 418) to become wider than a top portion 607a of the recess 604 (e.g., which is within the dielectric material 408), as illustrated in FIG. 6C. As also illustrated in FIG. 6C, a middle portion 607b of the recess is tapered from a diameter da of the top portion 607a to a diameter db of the bottom portion 607c of the recess 604. In another example, the middle portion 607b is substantially absent, and there is a more abrupt step jump of the diameter from da to db, e.g., based on the etching process used.

In an example, an appropriate etch process 512, such as an isotropic etch process, is used to etch the dielectric material 418 adjacent to the bottom portion 607c of the recess 604. As discussed herein previously, the dielectric materials 408 and 418 are compositionally different, and are etch selective with respect to each other. Accordingly, as illustrated in FIG. 6C, the etch process 512 that etches the dielectric material 418 adjacent to the sidewalls of the bottom portion 607c of the recess 604 does not substantially etch the dielectric material 408 adjacent to the top portion 607a of the recess 604.

Referring again to FIG. 5, the method 500 then proceeds from 512 to 516, where conductive material 505 is deposited within the recess 604, to form the interconnect feature 404, as also illustrated in FIG. 6D. As the conductive material 405 is deposited within the entire recess 604 using a single deposition process, no seam, interface, or grain boundary is formed between the top and middle portions of the interconnect feature 404, or between the middle and bottom portions of the interconnect feature 404. This completes formation of the interconnect layer 401 comprising the dielectric materials 408, 418, and the interconnect feature 404 extending within the dielectric materials.

Referring again to FIG. 5, the method 500 then proceeds from 516 to 520, where layer 410 is formed above the interconnect layer 401, as also illustrated in FIG. 6E. In an example, the layer 410 is an interconnect layer, and is formed using techniques to form an interconnect layer. Thus, in IC 400 in FIG. 6E is similar to the IC 400 of FIGS. 4A-4C.

Note that the processes in method 500 are shown in a particular order for ease of description. However, one or more of the processes may be performed in a different order or may not be performed at all (and thus be optional), in accordance with some embodiments. Numerous variations on method 500 and the techniques described herein will be apparent in light of this disclosure.

### Example System

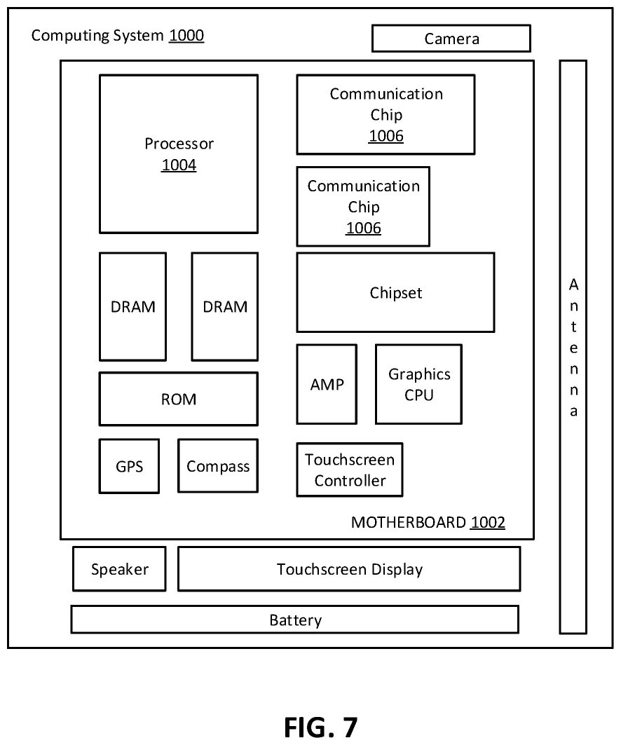

FIG. 7 illustrates a computing system 1000 implemented with integrated circuit structures and/or the interconnect features formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following examples pertain to further embodiments, from which numerous permutations and configurations will be apparent.

Example 1. An integrated circuit device comprising: a device layer comprising a plurality of transistor devices; and an interconnect layer above the device layer, the interconnect layer comprising an interconnect feature, the interconnect feature including (i) a bottom portion having a first diameter, and (ii) a top portion above the bottom portion, the top portion having a second diameter that is less than the first diameter by at least 10%, wherein the interconnect feature comprises a monolithic body of conductive material that is within both the top portion and the bottom portion.

Example 2. The integrated circuit device of example 1, wherein the second diameter is less than the first diameter by at least 15%.

Example 3. The integrated circuit device of any one of examples 1-2, wherein the second diameter is less than the first diameter by at least 25%.

Example 4. The integrated circuit device of any one of examples 1-3, wherein: the interconnect layer further comprises a dielectric material; and the interconnect feature, including the top portion and the bottom portion, extends through the dielectric material.

Example 5. The integrated circuit device of any one of examples 1-4, wherein: the interconnect layer further comprises a first dielectric material, and a second dielectric material above the first dielectric material; and the top portion of the interconnect feature is within the second dielectric material, and the bottom portion of the interconnect feature is within the first dielectric material.

Example 6. The integrated circuit device of example 5, wherein the first dielectric material and the second dielectric material are etch selective with respect to each other.

Example 7. The integrated circuit device of any one of examples 1-6, wherein the second diameter of the top portion transitions to the first diameter of the bottom portion along an irregular tapered portion of the interconnect feature.

Example 8. The integrated circuit device of example 7, wherein the irregular tapered portion of the interconnect feature extends from an upper perimeter of the irregular tapered portion to a lower perimeter of the irregular tapered portion, and one or both of the upper perimeter and the lower perimeter are curvilinear.

Example 9. The integrated circuit device of any one of examples 7-8, wherein the irregular tapered portion of the interconnect feature extends from an upper perimeter of the irregular tapered portion to a lower perimeter of the irregular tapered portion, and both of the upper perimeter and the lower perimeter are curvilinear.

Example 10. The integrated circuit device of any one of examples 7-9, wherein the irregular tapered portion of the interconnect feature extends from an upper perimeter of the irregular tapered portion to a lower perimeter of the irregular tapered portion, and wherein a first distance between a first point on the upper perimeter and a top surface of the interconnect feature is shorter than a second distance between a second point on the upper perimeter and the top surface of the interconnect feature.

Example 11. The integrated circuit device of example 10, wherein the first distance is at least 5 angstroms shorter than the second distance.

Example 12. The integrated circuit device of example 11, wherein the first distance is at least 10 angstroms shorter than the second distance.

Example 13. The integrated circuit device of any one of examples 7-12, wherein the irregular tapered portion of the interconnect feature extends from an upper perimeter of the irregular tapered portion to a lower perimeter of the irregular tapered portion, and wherein a first distance between a first point on the lower perimeter and a top surface of the interconnect feature is shorter than a second distance between a second point on the lower perimeter and the top surface of the interconnect feature.

Example 14. The integrated circuit device of example 13, wherein the first distance is at least 5 angstroms shorter than the second distance.

Example 15. The integrated circuit device of any one of examples 13, wherein the first distance is at least 10 angstroms shorter than the second distance.

Example 16. The integrated circuit device of any one of examples 1-15, wherein the top portion has a first height, and the bottom portion has a second height that is greater than the first height.

Example 17. The integrated circuit device of any one of examples 1-16, wherein the interconnect layer further comprises: a first dielectric material, wherein the interconnect feature, including both the top portion and the bottom portion, extends within the first dielectric material; and a second dielectric material between at least a section of the conductive material of the top portion of the interconnect feature and the first dielectric material, the second dielectric material different from the first dielectric material, wherein the second dielectric is absent between the conductive material of the bottom portion of the interconnect feature and the first dielectric material.

Example 18. The integrated circuit device of example 17, wherein the first dielectric material is etch selective with respect to the second dielectric material.

Example 19. The integrated circuit device of any one of examples 17-18, wherein a bottom perimeter of the second dielectric material is irregular and curvilinear.

Example 20. The integrated circuit device of any one of examples 1-19, wherein the interconnect layer further comprises: a first dielectric material, wherein the interconnect feature, including both the top portion and the bottom portion, extends within the first dielectric material; and one or more discontinuous monolayers of a second dielectric material between at least a section of the conductive material of the top portion of the interconnect feature and the first dielectric material, the second dielectric material different from the first dielectric material, wherein the second dielectric is absent between the conductive material of the bottom portion of the interconnect feature and the first dielectric material.

Example 20. An integrated circuit device comprising: a device layer comprising a plurality of active devices; and an interconnect layer above the device layer, the interconnect layer comprising an interconnect feature comprising a monolithic body of conductive material extending from a bottom surface of the interconnect feature to a top surface of the interconnect feature, wherein a first diameter of the bottom surface of the interconnect feature is greater than a second diameter of a top surface of the interconnect feature by at least 10%.

Example 21. The integrated circuit device of example 20, wherein the interconnect layer is a first interconnect layer, and wherein the integrated circuit device further comprises: an upper interconnect layer above the first interconnect layer, the upper interconnect layer comprising a plurality of upper conductive features arranged at a first pitch; and a lower interconnect layer below the first interconnect layer, the lower interconnect layer comprising a plurality of lower conductive features arranged at a second pitch that is different from the first pitch, wherein the interconnect feature conductively couples an upper conductive feature to a lower conductive feature.

Example 22. The integrated circuit device of example 21, wherein the first pitch is less than the second pitch.

Example 23. The integrated circuit device of any one of examples 21-22, wherein one or more of the plurality of upper conductive features are one or more conductive lines.

Example 24. The integrated circuit device of any one of examples 21-23, wherein one or more of the plurality of lower conductive features are one or more conductive lines.

Example 25. The integrated circuit device of any one of examples 21-24, wherein one or more of the plurality of lower conductive features are one or more contacts of one or more transistor devices of the device layer.

Example 26. The integrated circuit device of any one of examples 20-25, wherein the interconnect layer comprises: a bottom layer comprising a first dielectric material; and a top layer above the bottom layer, the top layer comprising a second dielectric material that is compositionally different from the first dielectric material, wherein a top portion of the interconnect feature is within the top layer, and a bottom portion of the interconnect feature is within the bottom layer.

Example 27. The integrated circuit device of example 26, wherein the first dielectric material is etch selective with respect to the second dielectric material.

Example 28. A method of forming an integrated circuit, comprising: forming one or more layers of dielectric material above a device layer that comprises a plurality of transistors; forming a recess extending within the one or more layers; widening a bottom portion of the recess, without correspondingly widening a top portion of the recess, such that a first diameter of the bottom portion of the recess is greater than a second diameter of the top portion of the recess by at least 10%; and subsequent to widening the bottom portion of the recess, depositing a monolithic body of conductive material within the recess, to form an interconnect feature within the recess, wherein the interconnect feature has (i) a bottom portion having the first diameter, and (ii) a top portion above the bottom portion, the top portion having the second diameter.

Example 29. The method of example 28, wherein the one or more layers of dielectric material comprises at least a first layer of a first dielectric material, and wherein the method further comprises: subsequent to forming the recess, lining the top portion of the recess with a liner layer comprising a second dielectric material that is different from and etch selective to the first dielectric material, wherein widening the bottom portion of the recess comprises etching the bottom portion of the recess using an etchant that does not substantially etch the liner layer, thereby widening the bottom portion of the recess, without correspondingly widening the top portion of the recess.

Example 30. The method of example 29, wherein during etching the bottom portion of the recess, the liner layer protects the top portion of the recess from being substantially etched.

Example 31. The method of any one of examples 28-30, wherein the one or more layers of dielectric material comprises (i) a first layer of a first dielectric material, and (ii) a second layer of a second dielectric material above the first layer, wherein the bottom portion of the recess is within the first dielectric material, wherein the top portion of the recess is within the second dielectric material, wherein the first dielectric material is etch selective with respect to the second dielectric material, and wherein widening the bottom portion of the recess comprises: etching the first dielectric material through the bottom portion of the recess using an etchant that does not substantially etch the second dielectric material, thereby widening the bottom portion of the recess, without correspondingly widening the top portion of the recess.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. An integrated circuit device comprising:
a device layer comprising a plurality of transistor devices; and
an interconnect layer above the device layer, the interconnect layer comprising an interconnect feature, the interconnect feature including (i) a bottom portion having a first diameter, and (ii) a top portion above the bottom portion, the top portion having a second diameter that is less than the first diameter by at least 10%, wherein the interconnect feature comprises a monolithic body of conductive material that is within both the top portion and the bottom portion.

2. The integrated circuit device of claim 1, wherein:
the interconnect layer further comprises a dielectric material; and
the interconnect feature, including the top portion and the bottom portion, extends through the dielectric material.

3. The integrated circuit device of claim 1, wherein:
the interconnect layer further comprises a first dielectric material, and a second dielectric material above the first dielectric material; and
the top portion of the interconnect feature is within the second dielectric material, and the bottom portion of the interconnect feature is within the first dielectric material.

4. The integrated circuit device of claim 3, wherein the first dielectric material and the second dielectric material are etch selective with respect to each other.

5. The integrated circuit device of claim 1, wherein the second diameter of the top portion transitions to the first diameter of the bottom portion along an irregular tapered portion of the interconnect feature.

6. The integrated circuit device of claim 5, wherein the irregular tapered portion of the interconnect feature extends from an upper perimeter of the irregular tapered portion to a lower perimeter of the irregular tapered portion, and one or both of the upper perimeter and the lower perimeter are curvilinear.

7. The integrated circuit device of claim 5, wherein the irregular tapered portion of the interconnect feature extends from an upper perimeter of the irregular tapered portion to a lower perimeter of the irregular tapered portion, and wherein a first distance between a first point on the upper perimeter and a top surface of the interconnect feature is shorter than a second distance between a second point on the upper perimeter and the top surface of the interconnect feature.

8. The integrated circuit device of claim 5, wherein the irregular tapered portion of the interconnect feature extends from an upper perimeter of the irregular tapered portion to a lower perimeter of the irregular tapered portion, and wherein a first distance between a first point on the lower perimeter and a top surface of the interconnect feature is shorter than a second distance between a second point on the lower perimeter and the top surface of the interconnect feature.

9. The integrated circuit device of claim 1, wherein the top portion has a first height, and the bottom portion has a second height that is greater than the first height.

10. The integrated circuit device of claim 1, wherein the interconnect layer further comprises:
a first dielectric material, wherein the interconnect feature, including both the top portion and the bottom portion, extends within the first dielectric material; and
a second dielectric material between at least a section of the conductive material of the top portion of the interconnect feature and the first dielectric material, the second dielectric material different from the first dielectric material,
wherein the second dielectric is absent between the conductive material of the bottom portion of the interconnect feature and the first dielectric material.

11. The integrated circuit device of claim 10, wherein the first dielectric material is etch selective with respect to the second dielectric material.

12. The integrated circuit device of claim 1, wherein the interconnect layer further comprises:
a first dielectric material, wherein the interconnect feature, including both the top portion and the bottom portion, extends within the first dielectric material; and
one or more discontinuous monolayers of a second dielectric material between at least a section of the conductive material of the top portion of the interconnect feature and the first dielectric material, the second dielectric material different from the first dielectric material,
wherein the second dielectric is absent between the conductive material of the bottom portion of the interconnect feature and the first dielectric material.

13. An integrated circuit device comprising:
a device layer comprising a plurality of active devices; and
an interconnect layer above the device layer, the interconnect layer comprising an interconnect feature comprising a monolithic body of conductive material extending from a bottom surface of the interconnect feature to a top surface of the interconnect feature,
wherein a first diameter of the bottom surface of the interconnect feature is greater than a second diameter of a top surface of the interconnect feature by at least 10%.

14. The integrated circuit device of claim 13, wherein the interconnect layer is a first interconnect layer, and wherein the integrated circuit device further comprises:
an upper interconnect layer above the first interconnect layer, the upper interconnect layer comprising a plurality of upper conductive features arranged at a first pitch; and
a lower interconnect layer below the first interconnect layer, the lower interconnect layer comprising a plurality of lower conductive features arranged at a second pitch that is different from the first pitch,
wherein the interconnect feature conductively couples an upper conductive feature to a lower conductive feature.

15. The integrated circuit device of claim 14, wherein one or more of the plurality of lower conductive features are one or more contacts of one or more transistor devices of the device layer.

16. The integrated circuit device of claim 13, wherein the interconnect layer comprises:
a bottom layer comprising a first dielectric material; and
a top layer above the bottom layer, the top layer comprising a second dielectric material that is compositionally different from the first dielectric material,
wherein a top portion of the interconnect feature is within the top layer, and a bottom portion of the interconnect feature is within the bottom layer.

17. The integrated circuit device of claim 16, wherein the first dielectric material is etch selective with respect to the second dielectric material.

18. A method of forming an integrated circuit, comprising:
forming one or more layers of dielectric material above a device layer that comprises a plurality of transistors;
forming a recess extending within the one or more layers;
widening a bottom portion of the recess, without correspondingly widening a top portion of the recess, such that a first diameter of the bottom portion of the recess is greater than a second diameter of the top portion of the recess by at least 10%; and
subsequent to widening the bottom portion of the recess, depositing a monolithic body of conductive material within the recess, to form an interconnect feature within the recess, wherein the interconnect feature has (i) a bottom portion having the first diameter, and (ii) a top portion above the bottom portion, the top portion having the second diameter.

19. The method of claim 18, wherein the one or more layers of dielectric material comprises at least a first layer of a first dielectric material, and wherein the method further comprises:
subsequent to forming the recess, lining the top portion of the recess with a liner layer comprising a second dielectric material that is different from and etch selective to the first dielectric material,
wherein widening the bottom portion of the recess comprises
etching the bottom portion of the recess using an etchant that does not substantially etch the liner layer, thereby widening the bottom portion of the recess, without correspondingly widening the top portion of the recess.

20. The method of claim 18, wherein the one or more layers of dielectric material comprises (i) a first layer of a first dielectric material, and (ii) a second layer of a second dielectric material above the first layer, wherein the bottom portion of the recess is within the first dielectric material, wherein the top portion of the recess is within the second dielectric material, wherein the first dielectric material is etch selective with respect to the second dielectric material, and wherein widening the bottom portion of the recess comprises:
etching the first dielectric material through the bottom portion of the recess using an etchant that does not substantially etch the second dielectric material, thereby widening the bottom portion of the recess, without correspondingly widening the top portion of the recess.
